(19) United States
(12) Patent Application Publication
(10) Pub. No.: US 2007/0207562 A1
(43) Pub. Date: Sep. 6, 2007

(54) Method of Forming a Micromachined Device Using an Assisted Release

(75) Inventor: Bruce K. Wachtmann, Concord, MA (US)

Correspondence Address: BROMBERG & SUNSTEIN LLP, 125 SUMMER STREET, BOSTON, MA, 02110-1618, US

(73) Assignee: ANALOG DEVICES, INC., Norwood, MA (US)

(21) Appl. No.: 11/681,931

(22) Filed: Mar. 5, 2007

Related U.S. Application Data
(60) Provisional application No. 60/779,589, filed on Mar. 6, 2006.

(51) Int. Cl. H01L 21/00

(52) U.S. Cl. 438/48

(57) ABSTRACT

A method of forming a micromachined device embeds a first material within a sacrificial material, and then removes such first material to form a channel through the sacrificial material. The method then directs a sacrificial material removal fluid through the channel. The sacrificial material removal fluid removes at least a portion of the sacrificial material.

### PRIORITY

This patent application claims priority from provisional U.S. patent application No. 60/779,589, filed Mar. 6, 2006 entitled, “METHOD OF FORMING A MICROMACHINED DEVICE USING AN ASSISTED RELEASE,” and naming Bruce K. Wachtmann as inventor, the disclosure of which is incorporated herein, in its entirety, by reference.

### FIELD OF THE INVENTION

The invention generally relates microelectromechanical systems and, more particularly, the invention relates to methods of fabricating microelectromechanical systems and facilitating the process of releasing movable structure.

### BACKGROUND OF THE INVENTION

Microelectromechanical systems (“MEMS” or “MEMS devices”) are used in a growing number of applications. For example, MEMS currently are implemented as gyroscopes to detect pitch angles of airplanes, accelerometers to selectively deploy air bags in automobiles, and as microphones to capture audio signals. In simplified terms, such MEMS devices typically have a suspended structure above a substrate, and associated electronics that both senses movement of the suspended structure and delivers the sensed movement data to one or more external devices (e.g., an external computer). The external device processes the sensed data to calculate the property being measured (e.g., pitch angle or acceleration).

To form a MEMS device, some conventional micromachining processes deposit material ultimately intended to be the suspended structure upon an underlying sacrificial material. For example, a micromachining process may deposit polysilicon over a sacrificial oxide layer. This polysilicon, which ultimately will be the suspended structure, cannot move until the process removes the underlying sacrificial oxide layer. Conventional processes therefore “release” the suspended structure by removing much of the sacrificial oxide layer beneath it. To that end, such processes first may etch fluid channels through the suspended (but not yet released) structure to the oxide. After forming the channels, the process then may direct buffered oxide etchant to the oxide through the channels to remove much of the oxide. The process thus releases the suspended structure after the etchant removes a sufficient amount of the underlying oxide.

Undesirably, etching the fluid channels through the suspended structure necessarily removes some of its mass. Consequently, the overall device has a corresponding decrease in its inertial sensitivity.

### SUMMARY OF THE INVENTION

In accordance with one aspect of the invention, a method of forming a micromachined device embeds a first material within a sacrificial material, and then removes such first material to form a channel through at least a portion of the sacrificial material. The method then directs a sacrificial material removal fluid through the channel. The sacrificial material removal fluid removes at least a portion of the sacrificial material.

The method may perform additional processes. For example, the method also may form a movable element (also referred to as a “movable mass”) that is supported by the sacrificial material. The movable element is subsequently released when at least a portion of the sacrificial material is removed. In various cases, the sacrificial material removal fluid does not pass through the movable element.

In some embodiments, the method forms a flow path to the first material. The first material thus may be removed by directing a first material removal fluid through the flow path to the first material. Moreover, the sacrificial material removal fluid may be directed through the flow path and the channel. In illustrative embodiments, the first material is polysilicon and the first material removal fluid is xenon difluoride. In these or other embodiments, the sacrificial material is an oxide and the sacrificial material removing fluid is an oxide etchant.

In accordance with another embodiment of the invention, a method of forming a MEMS inertial sensor provides a substrate that supports a sacrificial layer, and forms a mass on the substrate. Specifically, the sacrificial layer is positioned between the mass and the substrate. Next, the method forms a channel through at least a portion of the sacrificial layer. At least a portion of the channel illustratively is positioned between the mass and the substrate. After the method forms the channel, it releases the mass.

Illustrative embodiments form the sacrificial layer so that it has a first material and a second material. Accordingly, to produce the channel, the method removes the first material from the sacrificial layer. Accordingly, the method releases the mass by directing a second material removal fluid through the channel to remove at least a portion of the second material.

The substrate may be a number of different types of substrates, such as a part of a bulk wafer, or it may be part of an silicon-on-insulator (“SOI”) wafer. Moreover, among other things, the inertial sensor may implement the functionality of an accelerometer or a gyroscope.

In accordance with another embodiment of the invention, a method of forming an inertial sensor forms a sacrificial layer, having first and second materials, above a substrate. After forming a sacrificial layer, the method forms a mass so that at least a portion of the sacrificial layer is positioned between the mass and the substrate. The method then removes the first material from the sacrificial layer to produce a channel within the sacrificial layer. At least a portion of the channel is positioned between the substrate and the mass. To release the mass, the method directs a second material removal fluid through the channel to remove at least a portion of the second material.

### BRIEF DESCRIPTION OF THE DRAWINGS

The foregoing advantages of the invention will be appreciated more fully from the following further description thereof with reference to the accompanying drawings. Those drawings are as described below.

FIG. 1 schematically shows a cross-sectional view of a MEMS device formed by illustrative embodiments of the invention. This view also corresponds to step 206 of the method of FIG. 2.

FIG. 2 shows a process of forming the MEMS device of FIG. 1 in accordance with illustrative embodiments.

FIG. 3 schematically shows a cross-sectional view of the MEMS device during fabrication corresponding to method step 200.

FIG. 4 schematically shows a cross-sectional view of the MEMS device during fabrication corresponding to method step 202.

FIG. 5 schematically shows a cross-sectional view of the MEMS device during fabrication corresponding to method step 204.

### DESCRIPTION OF ILLUSTRATIVE EMBODIMENTS

In illustrative embodiments, a method of forming a micromachined device embeds a first material within a sacrificial material supporting a mass, and then removes such first material to form a channel through the sacrificial material. The method then directs a sacrificial material removal fluid through the channel to remove at least a portion of the sacrificial material. This method consequently releases the mass without the need to form holes through it. Details of illustrative embodiments are discussed below.

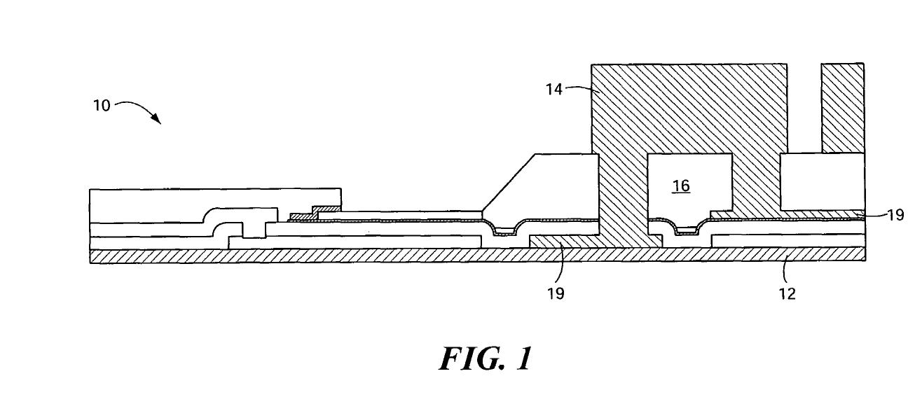

FIG. 1 schematically shows a cross-sectional view of a MEMS device 10 produced in accordance with illustrative embodiments of the invention. The device 10 includes a substrate 12 having an insulating layer and a plurality of additional components supported by the substrate 12. For simplicity, FIG. 1 generically shows the substrate without delineating the insulating layer on its top surface. In illustrative embodiments, the insulating layer is a thermal oxide.

The additional components include, among other things, a movable mass 14 (shown schematically as a single mass) spaced from the substrate, a plurality of flexures (not shown) coupling the mass 14 to the substrate 12, and circuitry (also not shown) to detect and/or control movement of the mass 14. A space between the substrate and the mass enables the mass 14 to move. Accordingly, the flexures, which also are referred to as springs, suspend the mass (i.e., movable element) above the substrate.

It should be noted that the term “above” is used herein to connote positioning from the perspective of the figures -not an absolute position relative to the earth. For example, when viewing FIG. 1 as intended (i.e., so the reference numbers upright), the substrate 12 is lower than the mass 14. Accordingly, if the MEMS device 10 is rotated so that its mass is closer to the ground or floor, the mass 14 still is considered to be suspended “above” the substrate.

The device 10 may be any conventionally known MEMS device, such as an inertial sensor. For example, the device 10 may be a gyroscope or an accelerometer. Exemplary MEMS gyroscopes are discussed in greater detail in U.S. Pat. No. 6,505,511, which is assigned to Analog Devices, Inc. of Norwood, Mass. Exemplary MEMS accelerometers are discussed in greater detail in U.S. Pat. No. 5,939,633, which also is assigned to Analog Devices, Inc. of Norwood, Mass. The disclosures of U.S. Pat. Nos. 5,939,633 and 6,505,511 are incorporated herein, in their entireties, by reference.

In a manner similar to those shown in these two patents, the mass 14 shown schematically in FIG. 1 may have one, two, or more individual masses that cooperate to provide movement data. In addition, instead of a sensor, alternative embodiments may implement other types of devices, such as microphones and pressure sensors. Accordingly, discussion of inertial sensors and specific types of sensors is not intended to limit the scope of all embodiments.

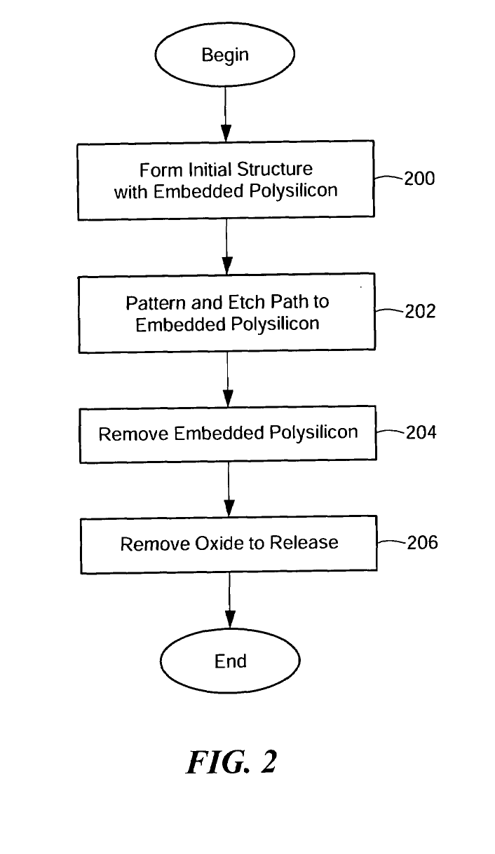

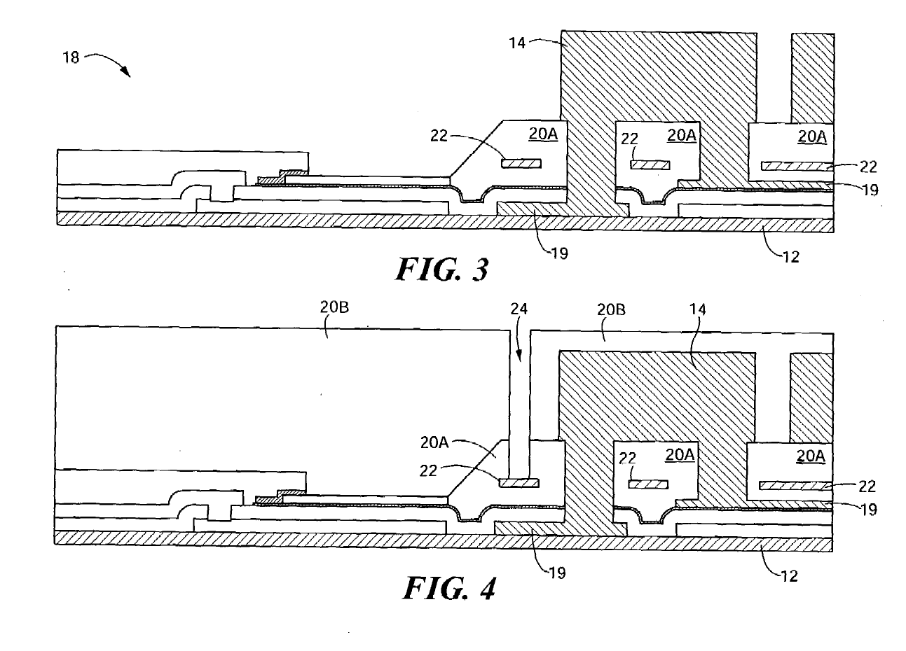

FIG. 2 shows a process of forming the MEMS device 10 shown in FIG. 1 in accordance with illustrative embodiments of the invention. The process begins at step 200, which forms the initial structure 18 shown in FIG. 3. Among other things, the initial structure 18 includes the above noted mass 14, which is supported by a sacrificial layer comprising materials identified in FIGS. 3 and 4 by reference numbers 20A and 22. Those materials are discussed in detail below. For simplicity, this sacrificial layer generally is referred to herein as “sacrificial layer 20A/22.” To form the mass 14 and sacrificial layer 20A/22, conventional processes illustratively form the sacrificial layer on underlying layers supported by the substrate 12. Next, processes deposit a doped polysilicon on the top surface of the sacrificial material 20A to form the mass 14. Of course, at this stage, the mass 14 is not moveable and thus, considered to be “unreleased.”

The initial structure 18 also has other layers, such as one or more internal conductive layers that permit the mass 14 to electrically connect with other components. Such layers are known in the art as “groundplanes” and identified in the drawings by reference number 19. In illustrative embodiments, conventional surface micromachining processes form the groundplanes 19 by depositing and patterning doped polysilicon on underlying insulating layers, and then, at some subsequent step, interconnecting them with the mass 14.

Various materials, layers, and other components in the initial structure 18 (and in the final product 10) can vary from those discussed above. For example, one type of device may be fabricated for an application that does not require a groundplane, or may not require on-chip circuitry. Accordingly, discussion of specific structure is not necessarily intended to limit a number of embodiments.

This discussion generally contemplates an embodiment that uses a bulk silicon substrate with additional layers that are deposited/grown, patterned, and/or etched to form the final product 10. Alternative embodiments, however, may implement silicon-on-insulator (“SOI”) processes. Accordingly, in that case, the substrate 12 and/or the mass 14 each may be formed at least in part from one of the silicon layers of a SOI wafer.

In accordance with illustrative embodiments, the sacrificial layer 20A/22 is formed from two separate materials; namely, an oxide sacrificial material 20A that at least partially encapsulates a second sacrificial material 22. Specifically, as discussed in greater detail below, the second sacrificial material 22 is embedded within the oxide sacrificial material 20A to effectively form a continuous internal channel 26 (see below) when removed. This internal channel 26 effectively facilitates mass release. Details of this process and benefits of this arrangement are discussed below.

In various embodiments, the second sacrificial material 22 is polysilicon. Accordingly, for illustrative purposes, the remainder of this process is discussed with the second sacrificial material 22 being polysilicon and the sacrificial material 20A being an oxide. Of course, those skilled in the art should understand that the materials used in the sacrificial layer 20A/22 are illustrative. Other materials capable of performing similar functions thus may be used.

A previously executed process may encapsulate the polysilicon sacrificial material 22 within the oxide sacrificial material 20A. For example, such a process may start with the substrate 12 having, at that point, multiple layers with an oxide as its top layer. The process then may deposit polysilicon on the oxide, and then deposit or grow additional oxide over the polysilicon. This additional oxide should integrate with the original oxide to effectively encapsulate the polysilicon that forms the second sacrificial material 22.

Alternatively, embodiments using SOI processes may have the polysilicon sacrificial material 22 integrated within the SOI buried oxide layer prior to forming any of the discussed components. Such an alternative structure is discussed in greater detail in U.S. patent application Ser. No. 10/308,688, filed Dec. 3, 2002, and entitled, “MEMS device with Alternative Electrical Connections,” the disclosure of which is incorporated herein, in its entirety, by reference.

The process continues to step 202, which first adds a photoresist layer 20B to the initial structure 18, and then patterns the layer 20B to form a mask. In addition to functioning as a mask, this photoresist layer 20B also protects at least a portion of the surface of the mass 14. Using the patterned layer 20B, this step then etches a flow path 24 (see FIG. 4) that, in illustrative embodiments, terminates at the second sacrificial material 22.

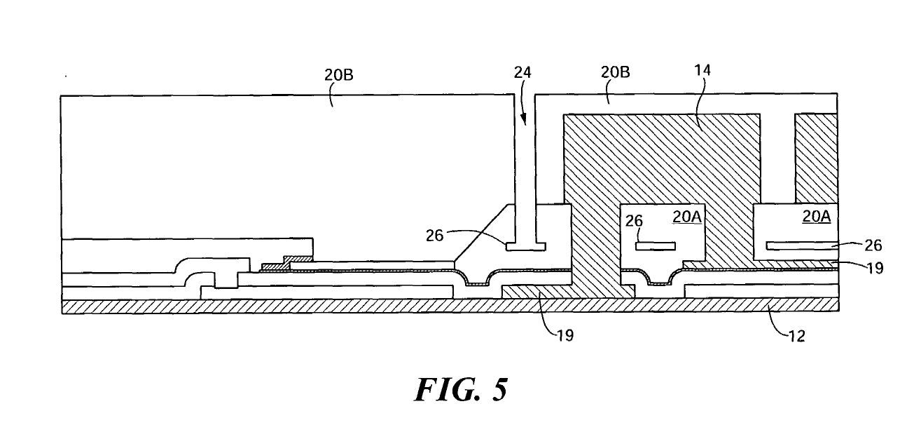

After forming a flow path 24, the process continues to step 204, which removes the embedded polysilicon 22. To that end, the method may direct a polysilicon removal fluid, such as xenon difluoride, through the flow path 24 to remove the embedded polysilicon 22. As known by those skilled in the art, the xenon difluoride should not remove any more than a negligible amount of the oxide 20A or photoresist 20B. As noted above and partially shown in FIG. 5, this step forms a continuous channel 26 within the sacrificial oxide 20A. At least a part of this channel 26 is positioned between the mass 14 and the substrate 12. In other words, the channel 26 is under the mass 14. The channel 26 thus provides as a ready path for a fluid capable of removing at least a part of the sacrificial oxide 20A.

It should be noted that a component that is “between” two other components does not necessarily mean that the component directly contacts the other two components. For example, the polysilicon 22 in the initial structure 18 of FIG. 3 is between the mass 14 and substrate 12, but does not contact either component 14 or 12.

The process thus concludes at step 206, which removes at least a portion of the oxide 20A to release the mass 14. To that end, the process may direct a buffered oxide etchant through the flow path 24 and channel 26, consequently removing the sacrificial oxide 20A. Accordingly, this process does not require buffered oxide etchant flow channels through the mass 14 to access the sacrificial oxide 20A. Consequently, the mass 14 should not lose a comparable amount of inertial sensitivity simply by removing the sacrificial oxide 20A. Although not optimal, however, some embodiments still may etch oxide etchant flow holes through the mass 14 to further facilitate release of the mass 14.

Conventional processes then may continue with additional steps to fabricate the device 10. For example, mask removal processes may remove the mask layer 20B, sawing processes may singulate the wafer forming the substrate 12, testing processes may test chip performance, and metallization processes may deposit metal contacts to provide a port for electrical communication. The final product may be capped and/or packaged in a conventional manner for use in a larger system. For example, if the final product is an accelerometer, it may be implemented as part of an air bag deployment system within an automobile.

As noted above, discussion of specific materials is illustrative and thus, not intended to limit the scope of all embodiments. For example, as noted above, materials other than polysilicon and oxide may be used. The fluids used to remove the sacrificial material also may be different. Moreover, the discussed fluids may be in various forms, such as in gas form or liquid form. In illustrative embodiments, the fluid used to remove the embedded sacrificial material 22 should have no more than a negligible effect on the sacrificial material through which the channel 26 is formed. For example, as noted above, xenon difluoride should have no more than a negligible effect on the removal of the noted oxide.

Although the above discussion discloses various exemplary embodiments of the invention, it should be apparent that those skilled in the art can make various modifications that will achieve some of the advantages of the invention without departing from the true scope of the invention. For example, rather than forming a single channel 26, some embodiments may deposit the embedded sacrificial material 22 in multiple locations that ultimately form multiple channels 26. Each channel 26 may be accessible by separate flow paths 24, or multiple interconnected flow paths 24. As another example, a single embedded sacrificial material 22 may be accessed by multiple flow paths 24.

What is claimed is:

1. A method of forming an inertial sensor, the method comprising:
forming a sacrificial layer above a substrate, the sacrificial layer having a first material and a second material;
forming a mass after forming a sacrificial layer, at least a portion of the sacrificial layer being between the mass and the substrate;
removing the first material from the sacrificial layer to produce a channel within the sacrificial layer, at least a portion of the channel being between the substrate and the mass; and
directing a second material removal fluid through the channel to remove at least a portion of the second material, directing releasing the mass.

2. The method as defined by claim 1 wherein the second material at least partially encapsulates the first material.

3. The method as defined by claim 1 wherein the second material removal fluid does not pass through the movable member.

4. The method as defined by claim 1 further comprising forming a flow path to the first material, removing comprising directing a first material removal fluid through the flow path to the first material.

5. The method as defined by claim 4 wherein directing a second material removal fluid through the channel comprises directing the second material removal fluid through the flow path and the channel.

6. The method as defined by claim 1 wherein the first material comprises polysilicon and the second material comprises an oxide.

7. The method as defined by claim 1 wherein the mass is substantially free of holes therethrough.

8. A method of forming a micromachined device, the method comprising:
embedding a first material within a sacrificial material;
removing at least a portion of the first material to form a channel through the sacrificial material; and
directing a sacrificial material removal fluid through the channel, the sacrificial material removal fluid removing at least a portion of the sacrificial material.

9. The method as defined by claim 8 further comprising:
forming a movable element that is supported by the sacrificial material, the movable element being released when at least a portion of the sacrificial material is removed.

10. The method as defined by claim 9 wherein the sacrificial material removal fluid does not pass through the movable element.

11. The method as defined by claim 8 further comprising forming a flow path to the first material, removing comprising directing a first material removal fluid through the flow path to the first material.

12. The method as defined by claim 11 wherein directing a sacrificial material removal fluid through the channel comprises directing the sacrificial material removal fluid through the flow path and the channel.

13. The method as defined by claim 11 wherein the first material comprises polysilicon and the first material removal fluid comprises xenon difluoride.

14. The method as defined by claim 8 wherein the sacrificial material comprises an oxide, and the sacrificial material removing fluid comprises an oxide etchant.

15. The method as defined by claim 8 wherein the micromachined device includes an inertial sensor.

16. A method of forming a MEMS inertial sensor, the method comprising:
providing a substrate that supports a sacrificial layer;
forming a mass wherein the sacrificial layer is positioned between the mass and the substrate;
forming a channel through at least a portion of the sacrificial layer, at least a portion of the channel being between the mass and the substrate; and
after forming the channel, releasing the mass.

17. The method as defined by claim 16 wherein forming a channel comprises:
forming the sacrificial layer with a first material and a second material;
removing the first material from the sacrificial layer to produce the channel.

18. The method as defined by claim 17 wherein releasing the mass comprises directing a second material removal fluid through the channel to remove at least a portion of the second material.

19. The method as defined by claim 16 wherein the substrate is part of a SOI wafer.

20. The method as defined by claim 16 wherein the inertial sensor is one of an accelerometer or a gyroscope.
